(19) United States
(12) Patent Application Publication
(10) Pub. No.: US 2020/0357601 A1
(43) Pub. Date: Nov. 12, 2020

(54) CHARGED PARTICLE BEAM DEVICE

(71) Applicant: HITACHI HIGH-TECHNOLOGIES CORPORATION, Tokyo (JP)

(72) Inventors: Hirohisa ENOMOTO, Tokyo (JP); Wataru SUZUKI, Tokyo (JP); Munekazu KOYANAGI, Tokyo (JP); Shigeru HANEDA, Tokyo (JP); Hideki KIKUCHI, Tokyo (JP)

(21) Appl. No.: 16/608,926

(22) PCT Filed: May 25, 2018
(86) PCT No.: PCT/JP2018/020241

§ 371 Date: Oct. 28, 2019

(30) Foreign Application Priority Data
Jun. 7, 2017 (JP) 2017-112415

(51) Int. Cl. H01J 37/20

(52) U.S. Cl. CPC H01J 37/20; H01J 2237/202

(57) ABSTRACT

There is provided a technology for imparting attenuation while maintaining rigidity of a support member that reduces vibration of a sample stage when disturbance such as an environmental sound is applied to a device and vibrates the sample stage. A charged particle beam device according to the present disclosure includes a sample stage that can move a sample, an attenuation unit that attenuates vibration of the sample stage, and a sample chamber that stores the sample stage and the attenuation unit. In the charged particle beam device, the sample stage and the attenuation unit are disposed so as to be horizontal to each other. Also, the sample stage is configured to be supported so as to be sandwiched between the attenuation unit and a first side surface of a casing, and the inside of the casing of the attenuation unit is filled with a plural number of friction bodies.

### TECHNICAL FIELD

The present disclosure relates to a charged particle beam device.

### BACKGROUND ART

Usually, a charged particle beam device is installed on the floor of a room and the like. In such installation environment, when a disturbance such as the floor vibration and the environmental sound is applied to the charged particle beam device, the vibration is transmitted to a sample stage through a sample chamber, and causes image shaking. In order to reduce this vibration, various methods have been devised. For example, Patent Literature 1 discloses a damper that is interposed between a stage on which a sample is placed and a sample chamber wall. Also, Patent Literature 2 discloses a seismic isolation device installed between a building and the base (the ground) although it is a vibration reduction method by friction in another industrial device.

### CITATION LIST

### Patent Literature

Patent Literature 1: WO 00/16371

Patent Literature 2: Japanese Unexamined Patent

Application Publication No. 2006-242212

### SUMMARY OF INVENTION

### Technical Problem

In the sample stage, from the viewpoint of the usage, only one side is fixed to the sample chamber for easy taking out from the sample chamber. Therefore, the sample stage has a cantilever structure, and the distal end of the sample stage where the sample is placed is liable to vibrate. Accordingly, a highly rigid support member is pressed against the distal end of the sample stage from the sample chamber for supporting.

However, according to Patent Literature 1, a damper filled with a highly viscous fluid is installed at the distal end of the sample stage. The damper sandwiches a ring-like rubber member between a projected member and a recessed member having a circular cylindrical shape in order to seal the highly viscous fluid, and there is a problem that rigidity substantially drops although attenuation is imparted.

Also, according to Patent Literature 2, a hollow space is arranged inside a laminated body where rubber and steel sheets are laminated in the vertical direction, and the inside of the hollow space is filled with friction bodies of a spherical body and the like. Since this seismic isolation device has a seismic isolation structure supported by rubber, rigidity is low. Therefore, there is a problem that attenuation cannot be imparted while maintaining such high rigidity that is required for the support member of the sample stage.

The present disclosure has been achieved in view of such circumstances, and is to provide a technology for imparting attenuation while maintaining rigidity of a support member that reduces vibration of a sample stage when disturbance such as an environmental sound is applied to a device and vibrates the sample stage.

### Solution to Problem

A charged particle beam device according to the present disclosure includes a sample stage that can move a sample, an attenuation unit that attenuates vibration of the sample stage, and a sample chamber that stores the sample stage and the attenuation unit. In the charged particle beam device, the sample stage and the attenuation unit are disposed so as to be horizontal to each other. Also, the sample stage is configured to be supported so as to be sandwiched between the attenuation unit and a first side surface of a casing, and the inside of the casing of the attenuation unit is filled with a plural number of friction bodies.

Other features related to the present disclosure will be clarified by description of the present description and attached drawings. Also, embodiments of the present disclosure are achieved and realized by elements and combination of various elements, detailed description hereinafter, and embodiments of the attached claims.

It is to be understood that description of the present description is only a typical exemplification, and does not limit the claims or applications of the present disclosure in any meaning.

### Advantageous Effects of Invention

According to the present disclosure, when disturbance such as an environmental sound is applied to a charged particle beam device and vibrates a sample stage, vibration of the sample stage can be attenuated while maintaining rigidity of a support member that reduces vibration of the sample stage.

### BRIEF DESCRIPTION OF DRAWINGS

FIG. 1 is a drawing that shows a schematic cross-sectional configuration of a charged particle beam device according to an embodiment.

FIG. 2 is a drawing that shows a cross-sectional configuration of an attenuation unit of a charged particle beam device related to the first embodiment.

FIG. 3 is a drawing that shows a cross-sectional configuration of an attenuation unit of a charged particle beam device related to the second embodiment.

FIG. 4 are drawings each showing a cross-sectional configuration of an attenuation unit of a charged particle beam device related to the third embodiment.

FIG. 5 are drawings each showing a cross-sectional configuration of an attenuation unit of a charged particle beam device related to the fourth embodiment.

FIG. 6 is a drawing that shows a cross-sectional configuration of an attenuation unit of a charged particle beam device related to the fifth embodiment.

FIG. 7 is a drawing that shows a cross-sectional configuration of an attenuation unit of a charged particle beam device related to the sixth embodiment.

FIG. 8 is a drawing that shows a cross-sectional configuration of an attenuation unit of a charged particle beam device related to the seventh embodiment.

FIG. 9 is a drawing that shows a cross-sectional configuration of an attenuation unit of a charged particle beam device related to the eighth embodiment.

FIG. 10 is a drawing that shows a cross-sectional configuration of an attenuation unit of a charged particle beam device related to the ninth embodiment.

### DESCRIPTION OF EMBODIMENTS

Below, embodiments of the present disclosure will be explained referring to the attached drawings. In the attached drawings, there is also a case that elements that are same in terms of the function are expressed by a same reference sign. Further, although the attached drawings show concrete embodiments and implication examples which are in accordance with the principle of the present disclosure, they are only for understanding of the present disclosure and are not to be used for definitive interpretation of the present disclosure by any means.

Although the present embodiments are explained in detail in such sufficient manner that a person with an ordinary skill in the art implicates the present disclosure, it is to be understood that other implications and aspects are possible and configurations and structures can be changed and various elements can be replaced without departing from the range and the spirit of the technical thought of the present disclosure. Accordingly, descriptions hereinafter are not to be definitively interpreted.

In the charged particle beam device according to the present disclosure, a sample stage is supported so as to be sandwiched between an attenuation unit and a first side surface of a sample chamber, and the attenuation unit that is disposed so as to be horizontal to the sample stage holds a plural number of friction bodies in the inside (the friction bodies fill the inside of the attenuation unit). Such configuration is applicable to a charged particle beam device of a FIB (ion beam working device), a SEM (scanning electron microscope), a TEM (transmission electron microscope), and so on for example.

### (1) First Embodiment

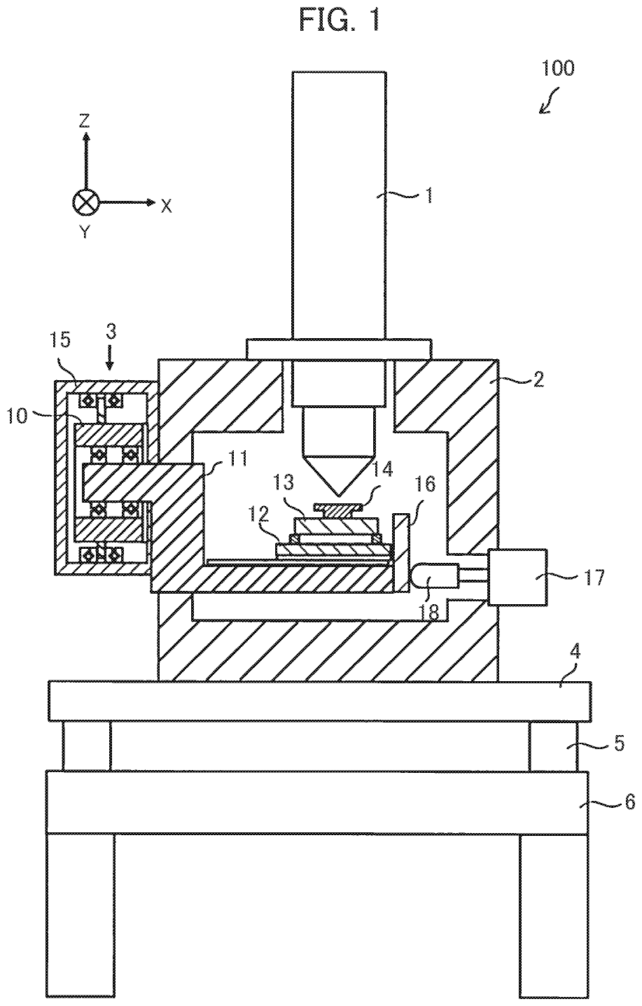

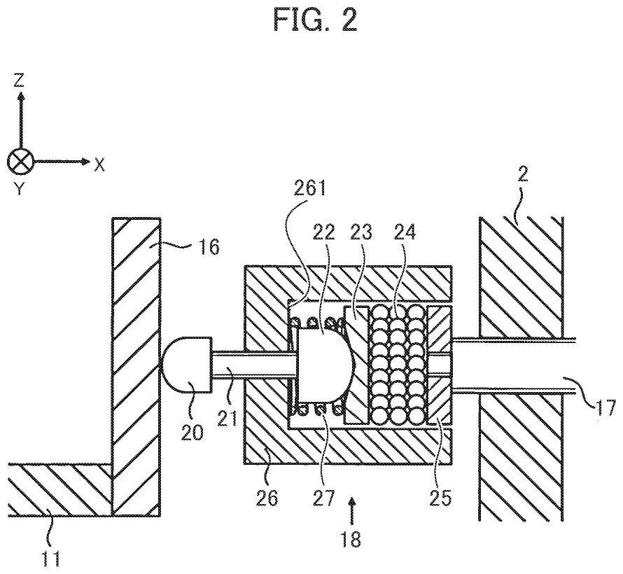

Below, the first embodiment of the present disclosure will be explained using FIGS. 1 and 2.

### <Overall Configuration of Charged Particle Beam Device>

FIG. 1 is a drawing that shows an overall schematic configuration of a charged particle beam device 100 according to an embodiment of the present disclosure. In the present embodiment, out of the charged particle beam device, an overall configuration of the device is shown exemplifying a SEM. However, the thought of the present disclosure is not limited to a SEM, and can be applied also to other charged particle beam device (FIB, TEM, and the like).

The SEM 100 according to the present embodiment includes a column 1 that outputs an electron beam, a sample chamber 2 that vacuum seals a sample, a sample stage 3 that moves the sample to a desired position so that the sample can be observed from various angles, a loading plate 4 that supports the column 1, the sample chamber 2, and the sample stage 3, a vibration isolation mount 5 that supports the loading plate 4 in a vibration isolation manner, and a pedestal 6 that supports the vibration isolation mount from beneath. The column 1 is disposed at the upper portion or on the side surface of the sample chamber, and the sample stage 3 is disposed on the side surface of the sample chamber.

Also, the sample stage 3 is configured of a Z-table 10 that is for moving the sample in the vertical direction, a tilt base 11 that is for tilting the sample around an axis that is parallel to the X-axis, an X-table 12 that is for moving the sample in the X-direction, a Y-table 13 that is for moving the sample in the Y-direction, a rotation table 14 that rotates the sample around an axis that is parallel to the vertical axis, and a stage case 15 that covers the Z-table 10, the X-table 12, the Y-table 13, and a part of the table tilt base 11, and they are assembled in order. Further, in the sample stage 3, an attenuation unit receive plate 16 receiving an attenuation unit 18 is disposed at the distal end, and the attenuation unit 18 is pressed against the attenuation unit receive plate 16 by an actuator 17.

Also, the direction for taking the sample stage 3 to the sample chamber 2 is made the X-direction, the direction that is orthogonal to the X-direction on a horizontal plane is made the Y-direction, and the vertical direction is made the Z-direction. Further, the constituents and the order and the configuration in assembling respective tables that configure the stage of the charged particle beam device according to the present disclosure are not limited to those described above.

### <Configuration of Attenuation Unit>

FIG. 2 is a drawing (cross-sectional view) that shows a cross-sectional configuration of the attenuation unit 18 of the charged particle beam device 100 according to the first embodiment of the present disclosure.

The attenuation unit 18 is disposed so as to be sandwiched by the attenuation unit receive plate 16 and the actuator 17. The distal end portion of the actuator 17 is made a rod, and is joined to the attenuation unit 18 by a thread portion of the distal end of the rod. Also, the attenuation unit 18 is only pressed against the attenuation unit receive plate 16 that expands in the Y-Z plane, and is not connected to the attenuation unit receive plate 16 by a joint element such as a screw and welding.

The attenuation unit 18 is supported by the actuator 17 and an actuator attaching plate 25 so as to be horizontal to the sample chamber 2. The actuator attaching plate 25 supports a friction body sealing case 26 horizontally, the friction body sealing case 26 storing friction bodies 24 that are configured of a lot of spherical bodies of metal, ceramic, and the like. Also, the friction body sealing case 26 supports a compression force adjustment screw 21 horizontally, the pressure adjustment screw 21 including a distal end pin 20 and a pressing pin 22. Further, from the attenuation unit receive plate 16 side toward the actuator 17, the distal end pin 20, the compression force adjustment screw 21, the pressing pin 22, a pressing plate 23, the friction bodies 24, and the actuator attaching plate 25 are configured by metal, the friction bodies 24 are configured by metal or ceramic, and these members are in contact with and connected to each other.

The friction bodies 24 are sandwiched by the pressing plate 23 and the actuator attaching plate 25 at both sides in the horizontal direction, and are surrounded by the friction body sealing case 26. Also, a tension spring 27 is arranged in the pressing plate 23 so that the pressing plate 23 follow the pressing pin 22 when the pressing pin 22 is moved to the left side of the paper surface. The both end portions of this tension spring 27 are fixed to the pressing plate 23 and an inner side wall 261 of the friction body sealing case 26 respectively, and the pressing plate 23 can thereby follow movement of the pressing pin 22.

Since the attenuation unit 18 is supported by contact of the metal (for example, each member configuring the attenuation unit 18) and the ceramic member (for example, the friction bodies 24) as described above, rigidity is increased compared to a case of using rubber and a resin. Also, since a viscous and elastic material such as rubber which is generally used as an attenuation member is not used, drift occurring when such member is pressed (when the member is pressed, although the pressing force does not change, displacement occurs in the viscous and elastic material) hardly occurs. Further, since there are a lot of contact portions, attenuation by friction is imparted.

Also, in the attenuation unit 18, among the components supported in series in the horizontal direction from the attenuation unit receive plate 16 side to the actuator 17, rigidity of the friction bodies 24 having a lot of the contact portions becomes lowest, and friction attenuation of the friction bodies 24 becomes largest. From these facts, rigidity and attenuation of the friction bodies 24 become dominant in rigidity and attenuation of the attenuation unit 18. Here, the friction attenuation described above means such phenomenon that a friction force generated by relative displacement between the friction bodies 24 (relative displacement occurs by vibration) is converted to thermal energy and kinetic energy is thereby dissipated.

By turning the compression force adjustment screw 21, the pressing pin 22 moves to either direction of the horizontal direction, and moves the pressing plate 23. Since the pressing plate 23 moves, a compression force applied to the friction bodies 24 changes. When the friction bodies are made spherical bodies as shown in the drawing, as the compression force applied to the friction bodies increases, rigidity of the contact portion of the friction bodies increases and the contact area affecting attenuation also increases. From this fact, rigidity and attenuation of the friction bodies 24 can be adjusted by adjustment of the compression force, adjustment of rigidity and attenuation of the attenuation unit becomes possible. However, the friction amount between the friction bodies (for example, the spherical bodies) 24 does not necessarily increases as the contact area of the friction bodies increases. Therefore, it is required to appropriately adjust the contact area between the friction bodies 24.

As shown in FIG. 2, the friction bodies 24 are mutually brought into contact with each other within a space that is formed by the pressing plate 23, the actuator attaching plate 25, and the friction body sealing case 26, and friction is generated by relative displacement occurring at the contact portions between the elements. The material of the friction bodies 24 can be metal, ceramic, or a compound material obtained by combination of them, and the Young's modulus of the material is within a range of 20-500 GPa. Further, although the shape of the friction bodies 24 is made a spherical body in the present embodiment, the shape of the friction bodies 24 is not limited to it, and can be a circular cylinder, a circular column, a rectangular parallelepiped, a circular cone, a truncated circular cone, a triangular prism, a pentagonal prism, a hexagonal prism, or a shape combining these shapes by plural numbers, as well as an irregular shape such as a sand particle. The number of pieces of the friction bodies 24 to be filled may be 2, but 3 or more is preferable. Also, the size of the friction bodies 24 is not required to be uniform, and the friction bodies 24 having different sizes may be filled appropriately. Further, although the pressing pin 22 and the pressing plate 23 are separated in applying a compression force to the friction bodies 24, the structure is not limited to the above as far as it is a structure capable of compressing the friction bodies, namely the pressing pin 22 and the pressing plate 23 are made to be an integrated structure for example and so on (in this case, the tension spring 27 is not necessary). Also, although the present embodiment is configured to press the attenuation unit 18 by the actuator 17, a structure of manual pressing is also possible.

By the configuration as described above, when disturbance such as an environmental sound is applied to the device and vibrates the sample stage, attenuation can be imparted while maintaining rigidity of the attenuation unit that reduces vibration of the sample stage, and drift occurring when the attenuation unit is pressed against the sample stage hardly occurs. Also, rigidity and attenuation can be adjusted according to a machine difference of the stage.

### (2) Second Embodiment

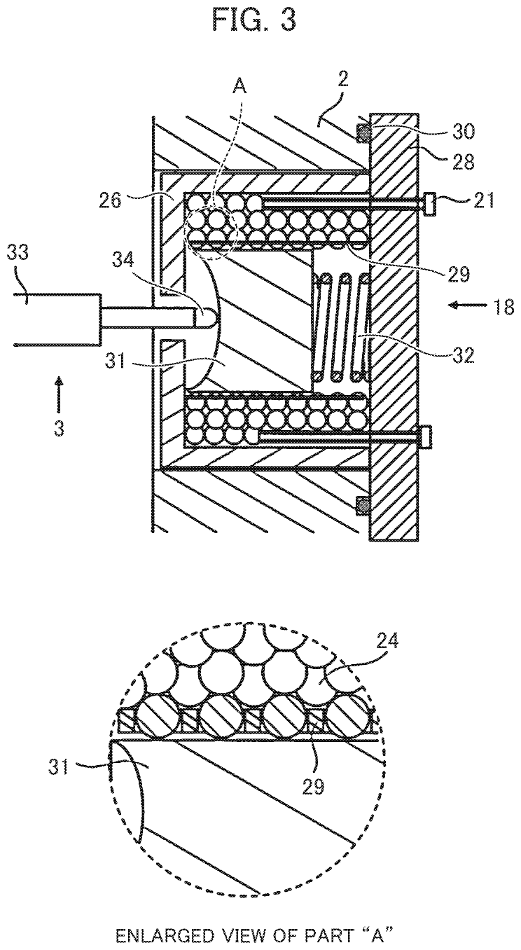

Below, the second embodiment of the present disclosure will be explained using FIG. 3. FIG. 3 is a drawing (cross-sectional view) that shows a cross-sectional structure of the attenuation unit 18 of a charged particle beam device according to the second embodiment of the present disclosure. Also, in FIG. 3, since a reference sign same to that of FIG. 1 or FIG. 2 expresses a same component, repeated explanation for the component will be omitted.

Although the attenuation unit 18 was disposed between the actuator 17 disposed in the wall of the sample chamber 2 and the attenuation unit receive plate 16 in the first embodiment, the attenuation unit 18 is incorporated in the wall of the sample chamber 2 in the second embodiment. That is to say, although the actuator 17 is made to be the fixed end of the attenuation unit 18 in the first embodiment, a sealing lid 28 described below is made to be the fixed end in the second embodiment.

For example, the inner wall of the sample chamber 2 is hollowed out into a circular shape, and the attenuation unit 18 is placed in the circular hole. The attenuation unit 18 is covered by the friction body sealing case 26 and the sealing lid 28. Inside the attenuation unit 18, the friction bodies 24, a friction body passing tube 29, a stage receiving component 31, and a pressing spring 32 are incorporated. Also, the compression force adjustment screw 21 is screwed to the inside of the attenuation unit 18 from the sealing lid 28. They configure the attenuation unit, and are configured to be fitted in from the outer wall of the sample chamber 2. The friction body passing tube 29 used in the present embodiment is configured by forming a plural number of holes regularly in a tubular member made of metal for example (a tubular member configured of so-called punching metal).

The friction body sealing case 26 is blocked by a circular plate having a circular cylindrical shape with one side of the circular cylinder being bored at the center. The sealing lid 28 is configured of a circular plate whose size is larger than the hole arranged in the inner wall of the sample chamber 2. The sample chamber 2 storing the friction body sealing case 26 in the inner wall thereof is vacuum sealed by an O ring 30 that is arranged on the side walls of the sealing lid 28 and the sample chamber 2. The end portion of the circular cylinder of the friction body sealing case 26 and the sealing lid 28 join to each other, and incorporate other components of the attenuation unit 18.

A lot of the circular holes are formed in the friction body passing tube 29. The friction body passing tube 29 is fittingly fixed to a groove (not illustrated) arranged in the circular plate portion of the friction body sealing case 26 and a groove (not illustrated) arranged in the sealing lid 28. Also, it is configured that a part of the friction bodies 24 enters the hole that is bored in the friction body passing tube 29. The size of the hole of the friction body passing tube 29 is set to such degree that a part of the friction bodies 24 protrudes to the opposite side of the plate of the friction body passing tube 29. Thus, the friction bodies 24 and the stage receiving component 31 come to contact each other.

The stage receiving component 31 has a circular column shape, and one side forms a spherical fulcrum. Thus it is configured that a spherical pin 34 located at the distal end of the stage holder can move, with being in contact with the surface of the spherical fulcrum while matching movement in the vertical direction and the left-right direction of the sample stage 3. Also, the stage receiving component 31 is incorporated in the friction body passing tube 29, and is configured that the outer periphery contacts the friction bodies 24. Further, the pressing spring 32 is disposed so as to be sandwiched between the stage receiving component 31 and the sealing lid 28, can push out the stage receiving component 31 to the left side of the paper surface, and can return the stage receiving component 31 to the original position.

The sample stage 3 may have such configuration that a stage holder 33 having a rod shape is inserted to the inside of the sample chamber 2 similarly to a sample stage used for a TEM, and may configured to be allowed to move in the axial direction and the axis perpendicular direction by the actuator 17.

The spherical pin 34 at the distal end of the stage holder 33 is supported by the friction body sealing case 26 or the sealing lid 28 and the sample chamber in this order through the stage receiving component 31 and the spherical bodies 24. Also, it is configured that the compression force of the spherical bodies 24 and the stage receiving component 31 can be adjusted by the compression force adjustment screw 21. That is to say, since the storage space of the friction bodies 24 becomes tight by an amount the compression force adjustment screw 21 is pushed in, the friction amount between the friction bodies 24 increases, and the level of absorbing vibration of the sample stage 3 by the friction can be controlled. Also, by the pressing spring 32 that is a compression spring, when the sample stage 3 is moved to the left side of the paper surface after movement to the right side of the paper surface, the stage receiving component 31 having been pushed in to the right side of the paper surface by the sample stage 3 comes to move to the left side following movement of the sample stage 3. Further, when the sample stage 3 vibrates, the vibration is transmitted from the stage holder 33 to the stage receiving component 31, and is transmitted from the stage receiving component 31 to the friction bodies 24.

With such configuration as described above, application to a stage structure of pressing the stage holder 33 having a rod shape as used in the TEM is also allowed, and the compression force to the attenuation unit 18 can be adjusted easily from the outside. Also, since insertion of the attenuation unit 18 from the outside is allowed, detachability improves.

### (3) Third Embodiment

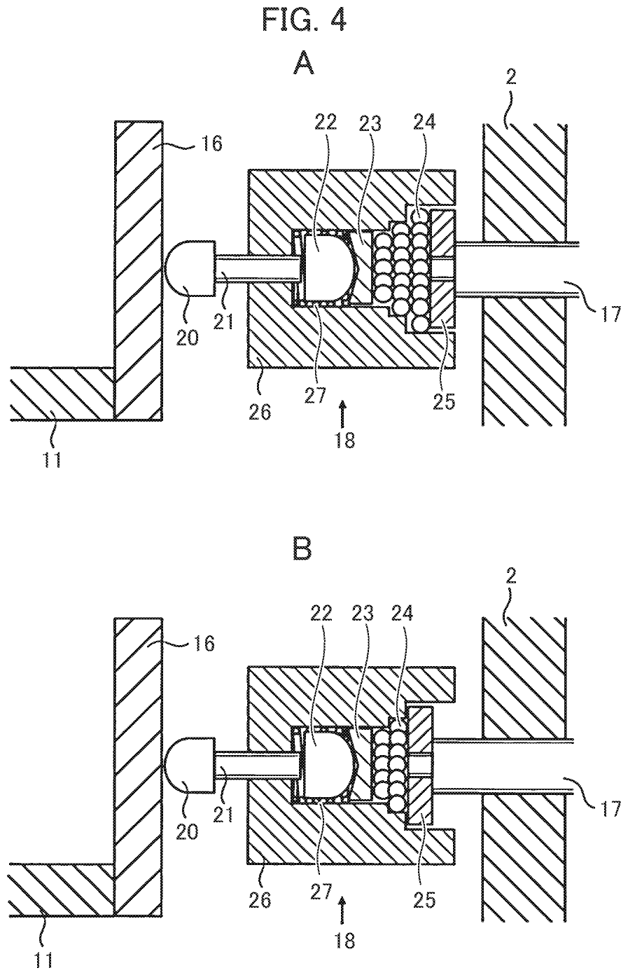

Below, the third embodiment of the present disclosure will be explained using FIG. 4. FIG. 4 are drawings (cross-sectional views) each showing a cross-sectional configuration of the attenuation unit 18 of a charged particle beam device according to the third embodiment. Also, in FIG. 4, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

In the third embodiment, a plural number of steps are arranged inside the friction body sealing case 26. Also, the height of the step may be made to be a degree same to the height of the spherical bodies filled in the inside. Thus, height adjustment is facilitated using the step as a mark.

In a case of filling by a lot of the spherical bodies (the friction bodies 24), all steps are filled with the friction bodies 24 as shown in FIG. 4A. On the other hand, in a case of reducing filling of the spherical bodies (the friction bodies 24), the filling height of the friction bodies 24 is changed (the steps is reduced) as shown in FIG. 4B, and the filling amount of the friction bodies 24 is adjusted. Thus, by arranging the steps arranged in the friction body sealing case 26 and adjusting the number of pieces of the friction bodies 24 to be stored, rigidity and friction attenuation of the attenuation unit 18 can be changed substantially.

With such configuration as described above, in stages of various machine kinds with different rigidity also, by changing the number of pieces of the friction bodies (balls) 24 to be filled, rigidity of the attenuation unit 18 comes to be allowed to be adjusted without substantially changing the structure of the attenuation unit 18. Further, although the steps are arranged in the present embodiment, grooves and the like may be arranged as far as they become the marks.

### (4) Fourth Embodiment

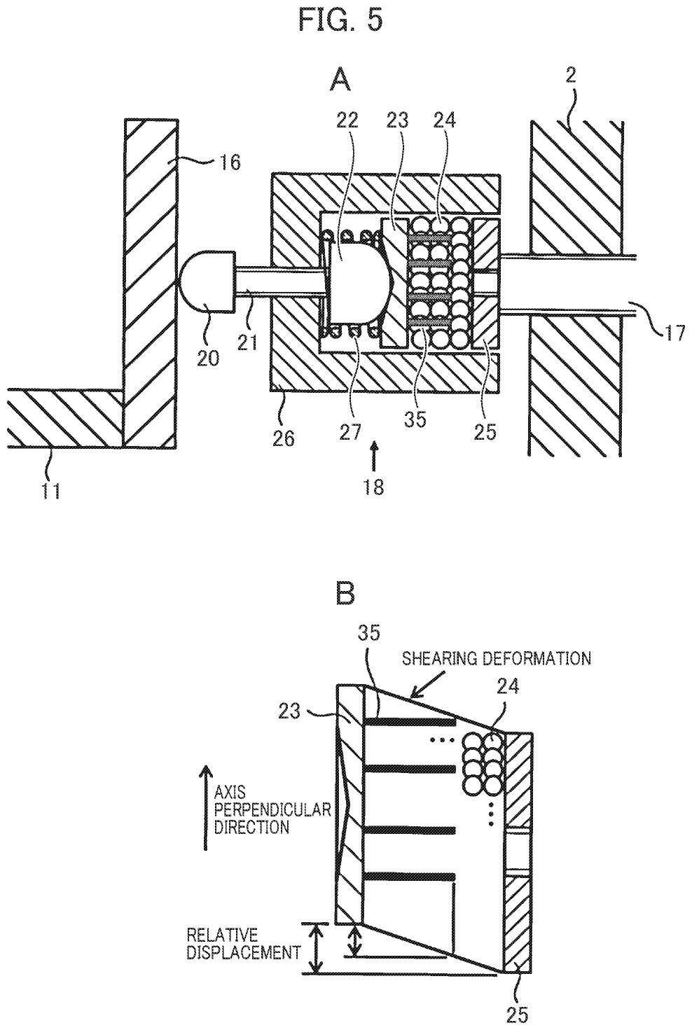

Below, the fourth embodiment of the present disclosure will be explained using FIG. 5. FIG. 5 are drawings (cross-sectional views) each showing a cross-sectional configuration of the attenuation unit 18 of a charged particle beam device according to the fourth embodiment of the present disclosure. Also, in FIG. 5A and FIG. 5B, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

As shown in FIG. 5A, according to the present embodiment, projections 35 are arranged in the pressing plate 23 at a predetermined interval (disposal between respective projections is not necessarily be at an equal interval). With respect to the projection 35, anything will do as far as it is a bar-like member such as a bolt and a rod. Here, it is preferable that the cross section of the projection 35 is smaller than the spherical body diameter of the friction bodies.

As shown in FIG. 5B, when the stage 3 is displaced in the axis perpendicular direction (the Y-axis direction or the Z-direction) and moves the pressing plate 23 in the axis perpendicular direction, since shearing deformation is caused in the friction bodies 24, as the distance between the pressing plate 23 and the friction bodies 24 is farther, relative displacement caused between the friction bodies 24 and the pressing plate 23 becomes larger. At this time, by the projections 35 arranged in the pressing plate 23, deformation of the pressing plate 23 acts to the inside of the friction bodies 24. Thus, relative displacement between the friction bodies 24 and the projections 35 namely the friction amount becomes large, and the attenuation effect is improved.

Also, the pressing plate 23 may have a thin plate structure. Thus, displacement of the sample stage 3 in the axial direction (the X-direction) causes the pressing plate 23 to be deformed in the axial direction, this deformation acts to the inside of the friction bodies 24 by the projections 35, the friction amount increases, and the attenuation effect is improved.

By such configuration as described above, since vibration of the pressing plate 23 is transmitted to the entire friction bodies 24 by the projections 35, friction attenuation increases.

### (5) Fifth Embodiment

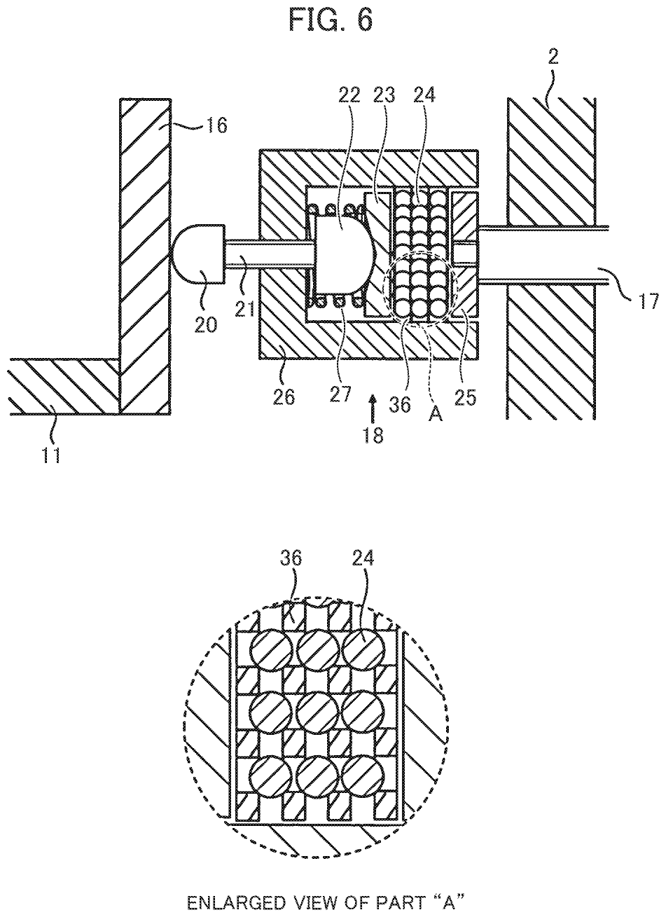

Below, the fifth embodiment of the present disclosure will be explained using FIG. 6. FIG. 6 is a drawing (cross-sectional view) that shows a cross-sectional configuration of the attenuation unit 18 of a charged particle beam device according to the fifth embodiment of the present disclosure. Also, in FIG. 6, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

Although the friction body sealing case 26 is filled only with the friction bodies 24 of the spherical bodies in the first embodiment, a threshold plate 36 is disposed between the friction bodies 24 and the friction bodies 24, holes being bored in the threshold plate 36, and the friction bodies 24 which are spherical bodies are fittingly stored in the holes (for example, the diameter of the hole is smaller than the diameter of the spherical body) of the threshold plate 36. For example, the threshold plates 36 and the friction bodies 24 are disposed alternately in such manner that the threshold plate 36 is disposed, the friction bodies 24 are arrayed then by one step, the threshold plate 36 is thereafter disposed further, the friction bodies 24 are arrayed by one step so as to be fitted into the hole of the threshold plate 36.

By disposing the threshold plate 36, holes with a same size being bored in the threshold plate 36, such structure of the attenuation unit 18 can be achieved in which the friction bodies 24 are arrayed uniformly at determined positions and the machine difference is small. Also, by changing the number of steps of the threshold plates 36 and the friction bodies 24, rigidity and attenuation of the attenuation unit 18 can be variably adjusted.

With such configuration as described above, such attenuation unit 18 can be achieved that dispersion of the friction bodies 24 is prevented, the position and the size of the holes arranged in the threshold plates 36 are fixed, therefore the machine difference is small, and rigidity and attenuation can be variably adjusted.

### (6) Sixth Embodiment

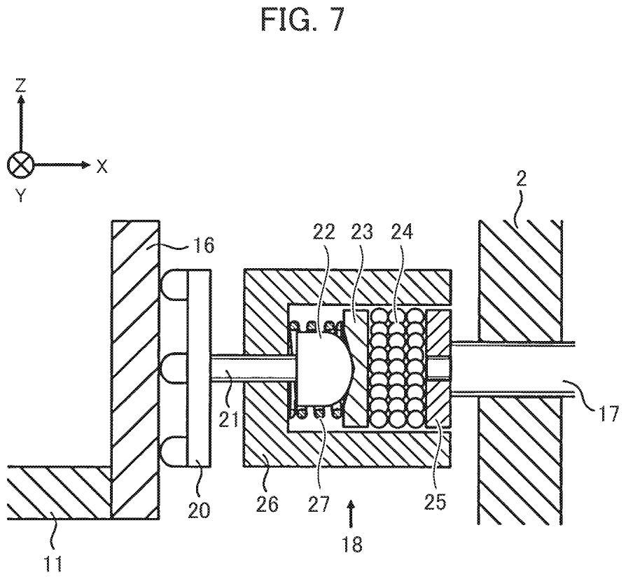

Below, the sixth embodiment of the present disclosure will be explained using FIG. 7. FIG. 7 is a drawing that shows a cross-sectional configuration of the attenuation unit 18 of a charged particle beam device according to the sixth embodiment of the present disclosure. Also, in FIG. 7, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

The attenuation unit receive plate 16 was supported by the distal end pin 20 at its one point in the first embodiment (refer to FIG. 2). However, according to the sixth embodiment, a portion (the attenuation unit receive plate 16) pressed by the distal end pin 20 is supported by a plural number of points (for example 3 points in FIG. 7). In order to support the attenuation unit receive plate 16 by a plural number of points, the distal end pin 20 includes the compression force adjustment screw 21 at the center of the plate portion and a plural number (for example 3 pieces) of pins at positons apart from the center of the plate, and is configured to press respective pins against the attenuation unit receive plate 16 and to support the attenuation unit receive plate 16.

By employing such configuration as described above, stability in supporting the attenuation unit receive plate 16 by the distal end pin 20 improves.

### (7) Seventh Embodiment

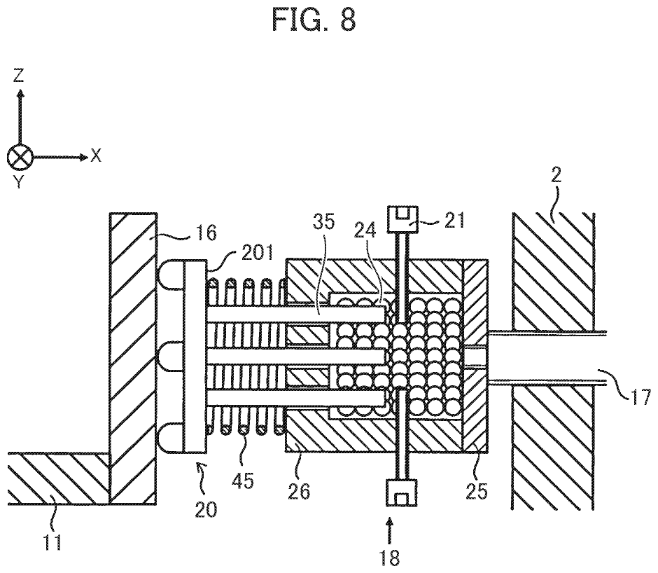

Below, the seventh embodiment of the present disclosure will be explained using FIG. 8. FIG. 8 is a drawing that shows a cross-sectional configuration of the attenuation unit 18 of a charged particle beam device according to the seventh embodiment of the present disclosure. Also, in FIG. 8, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

The pressing force adjustment screw 21 is fixed to the distal end pin 20 and is disposed on the end surface of the friction body sealing case 26 according to the sixth embodiment (refer to FIG. 7). However, according to the seventh embodiment, the pressing force adjustment screw 21 is disposed in the circular cylindrical surface of the friction body sealing case 26. Also, it is constructed that a plural number of the projections 35 are disposed in a plate member 201 of the distal end pin 20 and the projections 35 are inserted to the inside of the friction bodies 24 through holes bored in the end surface of the friction body sealing case 26. Further, in order to improve stability of the distal end pin 20 including the projections 35, a support spring 45 is arranged between the plate member 201 of the distal end pin 20 and the friction body sealing case 26. The support spring 45 can be fixed to the plate member 201 and the friction body sealing case 26 by adhesives, welding, and the like for example.

By such configuration as described above, adjustment of the pressing force adjustment screw 21 becomes easy, and stability in supporting the attenuation unit receive plate 16 by the distal end pin 20 is improved.

### (8) Eighth Embodiment

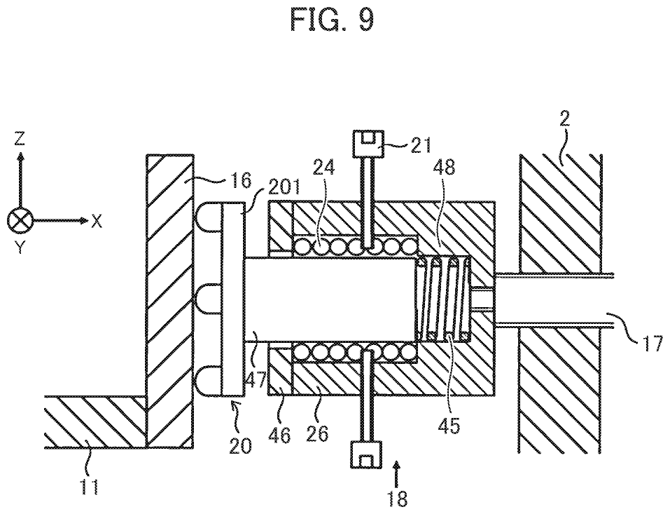

Below, the eighth embodiment of the present disclosure will be explained using FIG. 9. FIG. 9 is a drawing that shows a cross-sectional configuration of the attenuation unit 18 of a charged particle beam device according to the eighth embodiment of the present disclosure. Also, in FIG. 9, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

The projections are disposed in the plate member 201 of the distal end pin 20 in the seventh embodiment (refer to FIG. 8). However, according to the eighth embodiment, a rod 47 is attached to the center of the plate member 201, and the rod 47 portion is incorporated in the friction body sealing case 26. The rod diameter of the rod 47 is set to a size smaller than the friction body sealing case 26 and capable of filling the friction bodies 24 between the rod 47 and the friction body sealing case 26.

Also, the friction body sealing case 26 is configured as a circular cylinder whose one side is sealed, and is configured that the actuator 17 can be disposed on the sealing side. Further, a step 48 is arranged in the inner wall of the friction body sealing case 26, the opening end side of the inner wall is made wider, the back side of the inner wall is made narrower, and it is configured that a support spring 45 can be disposed on the back side. The support spring 45 is joined to the rod 47 that is attached to the distal end pin 20, and the friction body sealing case 26 by adhesives, welding, and the like for example, and supports the distal end pin 20 stably. However, the distal end pin 20 is supported mainly by the friction bodies 24 at the side surface of the rod 47. Also, before filling the friction bodies 24, the support spring 45 is used for supporting the distal end pin 20. Thus, assembling of the attenuation unit 18 is facilitated. Also, it is preferable that rigidity of the support spring 45 is set to be 1/10 or less of supporting rigidity by the friction bodies 24.

Further, a sealing lid 46 is disposed in the opening portion of the friction body sealing case 26, and prevents the friction bodies 24 from falling down from the friction body sealing case 26. Also, a hole is arranged at the center of the sealing lid 46, and it is configured that the rod 47 of the distal end pin 20 can penetrate the sealing lid 46.

By such configuration as described above, adjustment of the compression force adjustment screw 21 becomes easy, stability in supporting the distal end pin 20 is improved, and assembling of the attenuation unit 18 becomes easy.

### (9) Ninth Embodiment

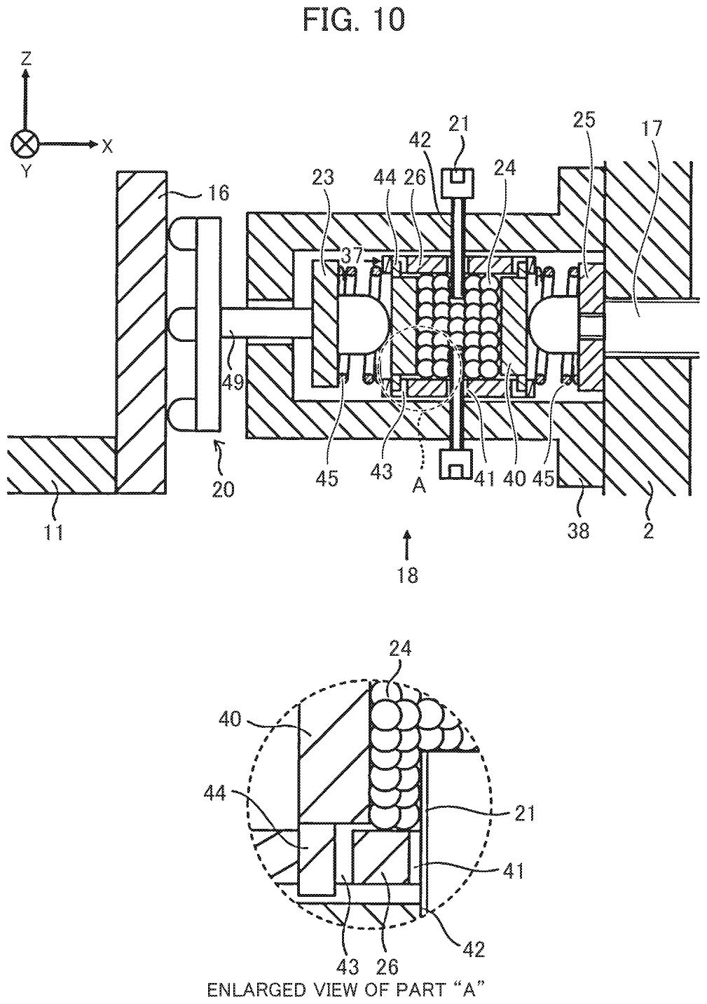

Below, the ninth embodiment of the present disclosure will be explained using FIG. 10. FIG. 10 is a cross-sectional view of the attenuation unit 18 of a charged particle beam device according to the ninth embodiment of the present disclosure. Also, in FIG. 10, since a reference sign same to that of FIG. 1 and FIG. 2 expresses a same component, repeated explanation for the component will be omitted. Further, although the friction bodies 24 are explained to be spherical bodies here, the friction bodies 24 are not limited to be spherical bodies.

According to the ninth embodiment, the fixing portion (the friction body sealing case 26) of the lid which seals the friction bodies 24 is made a movable structure, and it is constructed that a gap is arranged between a case (the friction body sealing case 26) and the compression force adjustment screw 21 so that relative displacement is caused between the compression force adjustment screw 21 and the friction bodies 24. The case seals the friction bodies 24.

The attenuation unit 18 includes, for example, the distal end pin 20, the pressing plate 23, a compression force damping section 37, the actuator attaching plate 25, and an attenuation unit support body 38. The distal end pin 20 includes a rod (having a thread structure (the compression force adjustment screw 21) in the first and sixth embodiments, but is a simple bar-like member instead of the thread structure in the ninth embodiment) 49, the pressing plate 23 has a circular plate shape, is provided with a spherical shape fulcrum at the center, and joins the distal end pin 20 through the rod. The actuator attaching plate 25 has a circular plate shape, is provided with a spherical shape fulcrum at the center, and joins the actuator 17. The attenuation unit support body 38 has a structure of a circular cylindrical shape whose one side being closed, is provided with a threaded hole in the vicinity of the center of the side surface, is provided with a through hole at the center of the closed surface of the circular cylinder, and is fixed to the side surface of the sample chamber.

In the attenuation unit 18, the actuator 17 and the actuator attaching plate 25 are supported by the side wall of the sample chamber 2. Also, the compression force damping section 37 is supported by the actuator attaching plate 25. The rod including the distal end pin 20 and the pressing plate 23 is supported by the compression force damping section 37. Thus, respective members from the attenuation unit receive plate 16 to the actuator 17 are supported horizontally. Also, by configuring the respective members of metal, rigidity of the attenuation unit 18 is secured. However, in order to improve stability of supporting of the attenuation unit 18, the support springs 45 are disposed between the pressing plate 23 and the friction body sealing case 26 and between the friction body sealing case 26 and the actuator attaching plate 25 respectively. The support springs 45 are fixed to the pressing plate 23 and the friction body sealing case 26 as well as the friction body sealing case 26 and the actuator attaching plate 25, respectively by adhesives, welding, and the like for example.

The compression force damping section 37 is located in the inside of the attenuation unit support body 38, and includes the friction body sealing case 26, sealing lids 40-1 and 40-2, the friction bodies 24, and the compression force adjustment screw 21. The friction body sealing case 26 has a circular cylindrical shape with through holes being bored at both ends and the center of the side surface. The sealing lids 40-1 and 40-2 are circular plates, provided with projections so as to seal the friction bodies 24 from both ends of the friction body sealing case 26 and to be fitted to the holes at both ends of the side surface of the friction body sealing case 26. The compression force adjustment screw 21 is capable of being screwed to the inside of the compression force damping section 37 through holes 41 at the center of the side surface of the friction body sealing case 26 and holes 42 at the center of the side surface of the attenuation unit support body.

The hole 41 at the center of the side surface of the friction body sealing case 26 is configured to be larger than the size (diameter) of the compression force adjustment screw 21, and it is configured that relative displacement is caused between the friction bodies 24 of the compression force damping section 37 and the compression force adjustment screw 21 fixed to the attenuation unit support body 38 by the gap between the hole 41 and the compression force adjustment screw 21. By this relative displacement, the total friction bodies are deformed, and attenuation occurs.

In the compression force damping section 37, projections 44 of the sealing lid are fitted into holes 43 of both ends of the side surface of the friction body sealing case 26. Also, the holes 43 of both ends of the side surface of the friction body sealing case 26 are configured to be larger compared to the projections 44 of the sealing lid. This configuration can function as a stopper with respect to a force toward the outside of the friction body sealing case 26.

Inside the friction body sealing case 26 are filled with the friction bodies 24 so that the projections 44 of the sealing lid can be constantly brought into contact with the holes 43 of both ends of the side surface of the friction body sealing case 26.

Since there is a gap between the projection 44 and the hole 43 described above, the sealing lid 40-1 on the sample stage 3 side is not supported by the friction body sealing case 26 against a force applied to the inside of the friction body sealing case 26 from the sample stage 3 side. Therefore, the force from the sample stage 3 comes to be supported by the friction bodies 24. Also, the friction bodies 24 are supported by the sealing lid 40-2 on the opposite side of the friction body sealing case 26 and the actuator attaching plate 25 in this order.

Since such structure of the attenuation unit 18 as described above is employed, when a force is applied to the attenuation unit 18 from the sample stage 3, the friction bodies 24 having lower rigidity compared to the fixing member such as the pressing plate 23 and the actuator attaching plate 25 deform, and the sealing lids 40-1 and 40-2 are pushed inward slightly. Thus, attenuation occurs in the friction bodies 24. On the other hand, even when the compression force adjustment screw 21 is pushed into the compression force damping section 37 and the friction bodies 24 are pushed out to the left and right of the paper surface, the projections 44 of the sealing lids 40-1 and 40-2 are pressed against and fixed to the side surface of the holes 43 of both ends of the side surface of the friction body sealing case. Accordingly, since a force in applying a compression force to the friction bodies 24 comes not to be directly applied to the sample stage 3 and the actuator 17, it is allowed to prevent the sample stage 3 from drifting when a compression force is applied.

By such configuration as described above, it can be configured that deformation of the friction bodies 24 is not transmitted to the sample stage 3 by the sealing lids 40-1 and 40-2 even when the compression force adjustment screw 21 is screwed into the compression force damping section 37.

Further, although the compression force to the friction bodies 24 inside the compression force damping section 37 is adjusted by the compression force adjustment screw 21 according to the present embodiment, it is also possible to incorporate a member having an extendible function such as a piezoelectric element inside the compression force damping section 37, to cause the member to extend/contract by a signal from the outside, and to adjust the compression force. Also, the compression force may be adjusted based on vibration data obtained by a sensor such as a piezoelectric element disposed in the attenuation unit 18.

### (10) Summary

According to the present embodiment, in the charged particle beam device, the sample stage and the attenuation unit that attenuates vibration of the sample stage are disposed horizontally (horizontally to the floor surface on which the charged particle beam device is installed). Also, it is constructed that the sample stage is supported so as to be sandwiched between on one side surface of the sample chamber of the charged particle beam device and the attenuation unit. Further, the inside of the casing of the attenuation unit is filled with a plural numbers of the friction bodies. With respect to the friction bodies, members configured of metal or ceramic can be employed. Thus, the attenuation unit is allowed to attenuate vibration by friction of respective friction bodies caused by vibration having been transmitted from the sample stage. Since the friction bodies have constant rigidity, rigidity of the attenuation unit can be maintained. Therefore, it can be made hard to cause drift when the sample stage is pressed against the attenuation unit.

According to the present embodiment (the first and third to sixth embodiments), the attenuation unit further includes the extendible adjustment screw that is extended from the attenuation unit toward the sample stage. The distal end of this adjustment screw is in contact with the sampled stage and supports the sample stage. Also, by this adjustment screw, vibration of the sample stage is transmitted to the friction bodies having been filled in the attenuation unit. This adjustment screw has a function of adjusting attenuation and rigidity of the attenuation unit. Thus, vibration of the sample stage comes to be transmitted to the friction bodies easily, and vibration comes to be allowed to attenuate vibration efficiently. Further it is also possible to arrange a plural number of the support portions at the distal end portion of the adjustment screw and to support the sample stage at plural points as done in the sixth embodiment. Thus, the sample stage comes to be allowed to be supported stably.

The second embodiment relates to a configuration that can be employed in a case of a sample stage for a TEM for example. Unlike the first embodiment and the like, the sample stage for a TEM includes a bar-like section that is inserted to the inside of the attenuation unit. Also, the attenuation unit includes the tubular member (for example, the punching metal member having a circular cylindrical shape) and the stage receiving member, the tubular member including a plural number of the holes into which the friction bodies are fitted, the stage receiving member being incorporated in the tubular member and receiving the distal end of the bar-like section. Further, the friction bodies fitted into a plural number of the holes of the tubular member are brought into contact with the surface of the stage receiving member other than the surface that receives the distal end of the bar-like section. By receiving the pin (the bar-like section) that is located on the sample stage side, on the attenuation unit side, vibration of the sample stage for a TEM also can be attenuated by a similar philosophy of the first embodiment. Also, in this case, the attenuation unit may be configured to be embedded in the inside (the side surface on the opposite side of the one side surface described above) of the sample chamber.

According to the third embodiment, the attenuation unit includes the steps in the inner space that holds the friction bodies. Also, it is preferable that the height of the step (the width of the step) is made to be a size generally same to the diameter of the friction body. Thus, the number of pieces of the friction bodies to be filled can be made variable, the magnitude of the friction energy generated by vibration can be adjusted by the number of pieces of the friction bodies, and therefore the attenuation function of the attenuation unit comes to be allowed to be adjusted.

According to the fourth embodiment, the attenuation unit includes a plural number of the projections (for example, the plate member suppressing the friction bodies, and the projections are arranged in the plate member on the surface opposite to the surface that is in contact with the friction bodies, the distal end of the adjustment screw described above being pressed against the plate member) extended in the horizontal direction. It is configured that the plural number of the projections are brought into contact with some of the plural number of the friction bodies having been filled. Since vibration is transmitted to the total friction bodies by such projections, vibration can be attenuated efficiently.

According to the fifth embodiment, in the attenuation unit, the threshold plate including a plural number of the holes having the diameter smaller than the diameter of the friction body is disposed in the space where a plural number of the friction bodies are filled. In this case, the friction bodies are filled so as to be fitted into a plural number of the holes of the threshold plate. Thus, dispersion of the friction bodies can be prevented, the machine difference can be reduced, and rigidity and attenuation function of the attenuation unit can be made variable.

According to the seventh embodiment, the attenuation unit includes the rod (not has a thread structure) and the adjustment screw. The rod includes the support portion supporting the sample stage, at the distal end. The adjustment screw is provided in the surface different from the surface to which the rod of the casing of the attenuation unit is attached (refer to FIG. 8) and adjusts attenuation and rigidity of the attenuation unit. Thus, the compression force imparted to the friction bodies comes to be allowed to be adjusted easily by the adjustment screw.

According to the eighth embodiment, in the configuration of the seventh embodiment (however, with respect to the rod, a rod having a larger diameter size compared to respective rods of the seventh embodiment is employed), it is configured that the friction bodies are filled between the side surface of the rod and the side surface of the inside of the casing of the attenuation unit. By such configuration also, the compression force imparted to the friction bodies can be adjusted easily by the adjustment screw, and the supporting function for the sample stage can be stabilized.

According to the ninth embodiment, in addition to the configuration of the seventh embodiment (although the rod is provided by one number in FIG. 10, such rod is employed that has a larger diameter size compared to respective rods of the seventh embodiment where a plural number of rods may be used), the attenuation unit has such structure of including the friction body holding casing in the inside of the casing of the attenuation unit. The friction body holding casing holds the friction bodies. In this case, the friction body holding casing has a structure of making the lid member movable, the lid member sealing the friction bodies, and the gap is arranged between the adjustment screw and the hole in the friction body holding casing so that relative displacement occurs between the adjustment screw and the friction bodies, the adjustment screw being inserted to the hole, (refer to FIG. 10). Thus, since displacement of the lid member is limited to a predetermined position even when the adjustment screw is screwed in to the friction bodies group and the compression force is increased, deformation of the friction bodies is not propagated to the sample stage, and drift of the sample stage can be prevented.

### LIST OF REFERENCE SIGNS

1 Column
2 Sample chamber
3 Sample stage
4 Loading plate
5 Vibration isolation mount
6 Pedestal
10 Z-table
11 Tilt base
12 X-table
13 Y-table
14 Rotation table
15 Stage case
16 Attenuation unit receive plate
17 Actuator
18 Attenuation unit
20 Distal end pin
21 Compression force adjustment screw
22 Pressing pin
23 Pressing plate
24 Friction body
25 Actuator attaching plate
26 Friction body sealing case
27 Tension spring
28 Sealing lid
29 Friction body passing tube
30 O ring
31 Stage receiving component
32 Pressing spring
33 Stage holder
34 Spherical pin
35 Projection
36 Threshold plate
37 Compression force damping section
38 Attenuation unit support body
40 Sealing lid
41 Hole at center of side surface of friction body sealing case
42 Hole in vicinity of center of side surface of attenuation unit support body
43 Holes at both ends of side surface of friction body sealing case
44 Projection of sealing lid

1. A charged particle beam device, comprising:
a sample stage that can move a sample;
an attenuation unit that attenuates vibration of the sample stage; and
a sample chamber that stores the sample stage and the attenuation unit, wherein
the sample stage and the attenuation unit are disposed so as to be horizontal to each other,
the sample stage is configured to be supported so as to be sandwiched between the attenuation unit and a first side surface of the sample chamber, and
the inside of a casing of the attenuation unit is filled with a plurality of friction bodies.

2. The charged particle beam device according to claim 1, wherein
the friction bodies are members configured of metal or ceramic.

3. The charged particle beam device according to claim 1, wherein
the attenuation unit further includes an extendible adjustment screw that is extended from the attenuation unit toward the sample stage, and the sample stage is supported by the adjustment screw.

4. The charged particle beam device according to claim 3, wherein
the attenuation unit receives vibration of the sample stage, and generates attenuation of the vibration by the plurality of the friction bodies.

5. The charged particle beam device according to claim 4, wherein
the adjustment screw adjusts attenuation and rigidity of the attenuation unit.

6. The charged particle beam device according to claim 1, wherein
the samples stage includes a bar-like section that is inserted to the inside of the attenuation unit,
the attenuation unit includes a tubular member and a stage receiving member, the tubular member including a plurality of holes into which the friction bodies are fitted, the stage receiving member being incorporated in the tubular member and receiving the distal end of the bar-like section of the sample stage, and
the friction bodies fitted into the plurality of the holes of the tubular member are brought into contact with a surface of the stage receiving member other than a surface that receives the distal end of the bar-like member.

7. The charged particle beam device according to claim 6, wherein
the attenuation unit is embedded in the inside of a second side surface that is different from the first side surface of the sample chamber.

8. The charged particle beam device according to claim 5, wherein
the attenuation unit includes a step in an inner space that is filled with the plurality of the friction bodies, and the number of piece of the plurality of the friction bodies to be filled is made variable, so that attenuation function of the attenuation unit is made adjustable.

9. The charged particle beam device according to claim 5, wherein
the attenuation unit includes a plurality of projections that are extended in the horizontal direction, and the plurality of projections are brought into contact with some of the plurality of the friction bodies having been filled.

10. The charged particle beam device according to claim 5, wherein
the attenuation unit includes a threshold plate in a space filled with the plurality of the friction bodies, the threshold plate including a plurality of holes having a diameter that is smaller than a diameter of the friction bodies, and
the plurality of the friction bodies are filled in the inside of the attenuation unit so as to be fitted into the plurality of the holes of the threshold plate.

11. The charged particle beam device according to claim 5, wherein
the adjustment screw includes a plurality of support portions that support the sample stage.

12. The charged particle beam device according to claim 1, wherein
the attenuation unit includes a rod and an adjustment screw, the rod including a support portion at the distal end, the support portion supporting the sample stage, the adjustment screw being provided at a surface different from a surface where the rod of a casing of the attenuation unit is attached, the adjustment screw adjusting attenuation and rigidity of the attenuation unit.

13. The charged particle beam device according to claim 12, wherein
the plurality of the friction bodies are filled between a side surface of the rod and an inner side surface of a casing of the attenuation unit, and
the side surface of the rod is supported by the friction bodies.

14. The charged particle beam device according to claim 12, wherein
the attenuation unit includes a friction body holding casing inside the casing of the attenuation unit, the friction body holding casing holding the plurality of the friction bodies,
the friction body holding casing has a structure of making a lid member movable, the lid member sealing the friction bodies, and
a gap is arranged between the adjustment screw and a hole in the friction body holding casing so that relative displacement occurs between the adjustment screw and the friction bodies, the adjustment screw being inserted to the hole.
